(19) United States
(12) Patent Application Publication
(10) Pub. No.: US 2009/0194237 A1
(43) Pub. Date: Aug. 6, 2009

(54) PLASMA PROCESSING SYSTEM

(75) Inventors: Toshihisa NOZAWA, Amagasaki-city (JP); Toshifumi KITAHARA, Amagasaki-city (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/362,769

(22) Filed: Jan. 30, 2009

(30) Foreign Application Priority Data
Jan. 31, 2008 (JP) 2008-020293

(51) Int. Cl. H01L 21/306; C23C 16/513

(52) U.S. Cl. 156/345.41; 118/723 ME

(57) ABSTRACT

A plasma processing system includes: a plasma processing apparatus which processes a substrate in a processing container by turning a processing gas supplied inside the processing container into plasma; and a carrier arm which carries the substrate in and out of the processing container, wherein a loading table is mounted inside the processing container and the substrate is loaded on the top surface of the loading table, and one or more recessed portions are formed on regions of the top surface of the loading table, wherein the regions corresponds to locations on the carrier arm for supporting the substrate. The coating layer is not transferred from the top surface of the loading table to the back of the substrate in the regions corresponding to the locations on the carrier arm for supporting the substrate. Accordingly, the coating layer is not transferred to the top surface of the carrier arm.

### CROSS-REFERENCE TO RELATED PATENT APPLICATION

This application claims the benefit of Japanese Patent Application No. 2008-020293, filed on Jan. 31, 2008, in the Japanese Patent Office, the disclosure of which is incorporated herein in its entirety by reference.

### BACKGROUND OF THE INVENTION

1. Field of the Invention

The present invention relates to a plasma processing system for processing a substrate by using plasma.

2. Description of the Related Art

A microwave-based plasma processing apparatus disclosed in Japanese Patent Publication No. 2006-203246 performs a film forming process or an etching process on a substrate, such as a silicon wafer. Also, a plasma processing apparatus disclosed in Japanese Patent Publication No. 2001-274142 generates plasma in a processing chamber by applying a high frequency voltage between an upper electrode and a lower electrode.

In such plasma processing apparatuses, a material having high conductivity, such as aluminum (Al), is used as a material for making a processing container that receives a substrate. However, Al particles may be generated due to plasma, thereby contaminating the substrate. Accordingly, such Al particles are prevented from being generated by forming, for example, a CF based coating layer on an inner side of the processing container.

However, when the CF based coating layer is formed on the inner side of the processing container, a CF based coating material of the CF based coating layer is also transferred on the top surface of a loading table which is exposed in the processing container, and thereby forming a CF based coating layer on the top surface of the loading table. Accordingly, when a substrate is put on the loading table, the CF based coating material of the CF based coating layer may be transferred on the back of the substrate, and moreover, the coating material transferred on the back of the substrate may be transferred on the top surface of a carrier arm (transfer arm), which carries the substrate in and out of the processing container of the plasma processing apparatus.

The coating material of the CF based coating layer may decrease the friction coefficient. Accordingly, if the coating material is transferred on the top surface of the carrier arm, the substrate may easily slide when the substrate is transferred on the top surface of the carrier arm. As a result, when the substrate slides on the carrier arm, the substrate may be wrongly transferred or a location of the substrate may change.

### SUMMARY OF THE INVENTION

The present invention provides a plasma processing system, which prevents a coating material from being transferred on the top surface of a carrier arm (transfer arm).

According to an aspect of the present invention, there is provided a plasma processing system including: a plasma processing apparatus which processes a substrate in a processing container by turning a processing gas supplied into the processing container into plasma; and a carrier arm which carries the substrate in and out of the processing container of the plasma processing apparatus, wherein a loading table is mounted inside the processing container and the substrate is loaded on the top surface of the loading table, and one or more recessed portions are formed on the top surface of the loading table, in correspondence to one or more locations on the carrier arm for supporting the substrate.

By forming the one or more recessed portions on the top surface of the loading table, a coating material is not transferred from the top surface of the loading table to the back of the substrate, in regions corresponding to locations on the carrier arm for supporting the substrate. Accordingly, the coating material is also not transferred to the top surface of the carrier arm.

A coating layer may be formed on an inner side of the processing container. The loading table may include a temperature adjusting unit which adjusts the temperature of the substrate.

A plurality of projections for supporting the back of the substrate may be formed on the top surface of the carrier arm, and the one or more recessed portions may be each formed on regions of the top surface of the loading table, wherein the regions correspond to the plurality of projections. The plasma processing system may further include a cleaning unit, which cleans the plurality of projections formed on the top surface of the carrier arm, outside the processing container. The cleaning unit may include a cleaning gas nozzle which ejects cleaning gas to the plurality of projections.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram for describing a plasma processing system according to an embodiment of the present invention;

FIG. 2 is a diagram for describing a carrier arm according to an embodiment of the present invention;

FIG. 3 is a cross-sectional view illustrating a schematic structure of a plasma processing apparatus;

FIG. 4 is a plan view of a loading table according to an embodiment of the present invention; and

FIG. 5 is a diagram for describing cleaning units according to an embodiment of the present invention.

### DETAILED DESCRIPTION OF THE INVENTION

Hereinafter, the present invention will be described more fully with reference to the accompanying drawings, in which exemplary embodiments of the invention are shown. In the drawings, like reference numerals denote like elements.

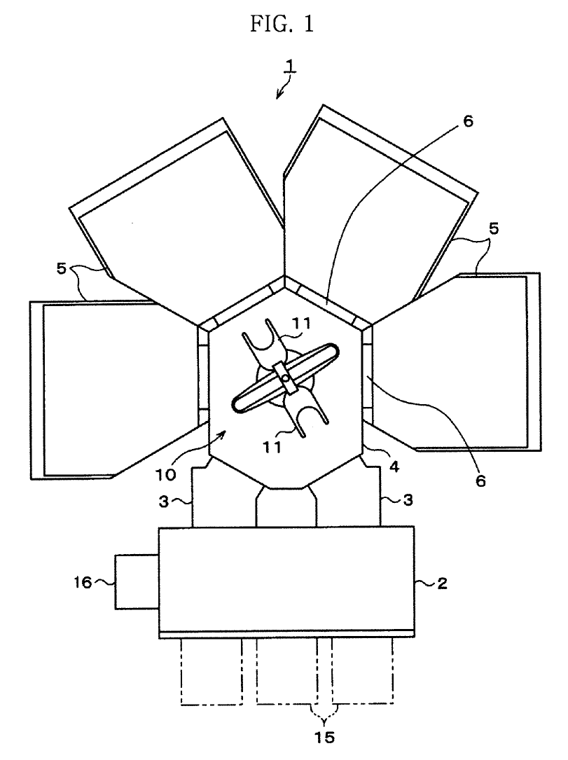

FIG. 1 is a diagram for describing a plasma processing system 1 according to an embodiment of the present invention. The plasma processing system 1 according to the current embodiment of the present invention includes a carry-in/out unit 2, which carries a wafer W as a substrate into and out of the plasma processing system 1, two load lock chambers 3, which are placed adjacent to the carry-in/out unit 2, a transfer chamber 4, which is placed adjacent to the each of the load lock chambers 3, and a plurality of plasma processing apparatuses 5, which are disposed around the transfer chamber 4. A gate valve 6 is mounted between each of the plasma processing apparatuses 5 and the transfer chamber 4.

A transfer apparatus 10 is placed in the transfer chamber 4 to carry the wafer W between the load lock chambers 3 and the plasma processing apparatuses 5. The transfer apparatus 10 includes a pair of carrier arms (transfer arms) 11 for supporting the wafer W. The internal transfer chamber 4 may be adapted to perform a suction operation in a vacuum state. In other words, when the internal transfer chamber 4 is in a vacuum state, the wafer W taken out from one of the load lock chambers 3 may be transferred to any one of the plasma processing apparatuses 5, and the wafer W carried out from any one of the plasma processing apparatuses 5 may be returned back to any one of the load lock chambers 3. Accordingly, the wafer W is carried in and out from the plasma processing apparatuses 5 while maintaining the plasma processing apparatuses 5 in a vacuum state.

Cassettes 15 are adjacently located to the carry-in/out unit 2, and the wafer W taken out from the cassettes 15 by the carry-in/out unit 2 is transferred to any one of the load lock chambers 3. Also, the wafer W taken out from any one of the load lock chambers 3 by the carry-in/out unit 2 is returned back to the cassettes 15. An alignment unit 16, which determines a location of the wafer W, is installed at the side of the carry-in/out unit 2.

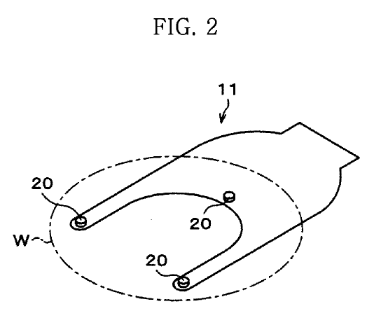

FIG. 2 is a diagram for describing the carrier arm 11 according to an embodiment of the present invention. As illustrated in FIG. 2, projections 20 for supporting the back of the wafer W are formed on three regions of the top surface of the carrier arm 11 included in the transfer apparatus 10. Accordingly, the wafer W is supported by the top surface of the three projections 20. The transfer apparatus 10 carries the wafer W on the carrier arm 11 between any one of the load lock chambers 3 and any one of the plasma processing apparatuses 5 in a state where the back of the wafer W contacts the top surface of the three projections 20.

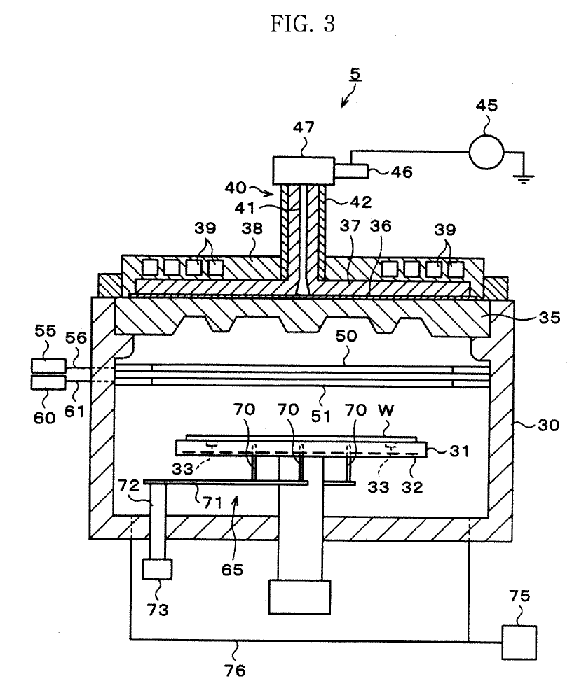

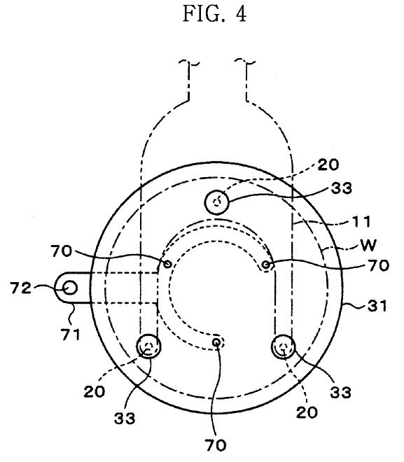

FIG. 3 is a cross-sectional view illustrating a schematic structure of the plasma processing apparatus 5. FIG. 4 is a plan view of a loading table (susceptor) 31 included in the plasma processing apparatus 5 according to an embodiment of the present invention, wherein the carrier arm 11 moved to the top surface of the loading table 31 is illustrated with alternated long and short dash lines.

As illustrated in FIG. 3, the plasma processing apparatus includes a processing container 30 having a cylindrical shape with opened top and closed bottom and formed of aluminum, for example. As will be described later, plasma treatment is performed on the wafer W inside the processing container 30. The inner walls of the processing container 30 are coated with a coating layer formed of a CF based coating material, and thus are protected from plasma. The processing container 30 is electrically grounded.

The loading table 31 has a cylindrical shape and is placed at the bottom portion of the processing container 30. The loading table 31 is loaded together with the wafer W in the processing container 30. The loading table 31 is formed of, for example, aluminum, and a temperature adjusting unit 32, such as a heater, is placed inside the loading table 31. The temperature adjusting unit 32 adjusts the temperature of the wafer W on the loading table 31 to a predetermined temperature.

In order for the temperature adjusting unit 32 to perform an accurate temperature adjustment, the entire back surface of the wafer W closely contacts the top surface of the loading table 31. Recessed portions 33 are formed on three regions (in FIG. 3, only two regions are shown) of the top surface of the loading table 31, wherein the three regions correspond to projections 20 of the top surface of the carrier arm 11 described above.

As illustrated in FIG. 4, when the carrier arm 11 is moved to the top of the loading table 31 while carrying the wafer W, the three projections 20 formed on the top surface of the carrier arm 11 are located directly above the recessed portions 33 formed on the top surface of the loading table 31. When seen from above, the recessed portions 33 have a larger area than the projections 20, and in a state where the carrier arm 11 is moved to the top surface of the loading table 31, the projections 20 are located inside the recessed portions 33. Accordingly, regions of the back of the wafer W that contact the projections 20 of the top surface of the carrier arm 11 do not contact the top surface of the loading table 31.

A transmission window 35, formed of a material such as a quartz member of a dielectric material, is mounted on the top opening of the processing container 30 via an O-ring for securing air-tightness. The transmission window 35 has a substantially disk-like shape. Instead of the quartz member, another dielectric material, for example, ceramics such as Al₂O₃, or AlN may be used.

An antenna member having a flat shape, for example, a radial line slot antenna 36 having a disk shape, is placed on the transmission window 35. The radial line slot antenna 36 is a thin copper disk plated or coated with a conductive material, such as Ag or Au. A plurality of slits for microwaves passage are formed in the radial line slot antenna 36. The slits are aligned, for example, in a spiral form or a concentrical form.

A wavelength-shortening plate 37 for reducing a wavelength of microwaves is placed on the top surface of the radial line slot antenna 36. The wavelength-shortening plate 37 is covered with a conductive cover 38. Thermal medium flow paths 39 in circular ring shapes are formed in the cover 38. The cover 38 and the transmission window 35 are maintained at a predetermined temperature due to a heating medium flowing through the thermal medium flow paths 39.

A coaxial waveguide 40 is connected to the center of the cover 38. The coaxial waveguide 40 includes an inner conductor 41 and an outer pipe 42. The inner conductor 41 contacts the radial line slot antenna 36 described above. The inner conductor 41 has a conical shape in the contact area with the radial line slot antenna 36, and thus efficiently transmits microwaves to the radial line slot antenna 36.

Microwaves, such as 2.45 GHz microwaves, generated by a microwave supplier 45 are transmitted to the transmission window 35 via a rectangular waveguide 46, a mode converter 47, the coaxial waveguide 40, the wavelength-shortening plate 37, and the radial line slot antenna 36. According to the energy of the microwaves, an electric field is formed below the transmission window 35, and thus plasma is formed inside the processing container 30.

An upper shower plate 50 and a lower shower plate 51, which form a gas supplier, are placed above the loading table 31 inside the processing container 30. The upper shower plate 50 and the lower shower plate 51 may be hollow pipes formed of quartz. Although not illustrated, the upper shower plate 50 and the lower shower plate 51 include a plurality of openings which are distributed to supply gas to the wafer W on the loading table 31.

A plasma generating gas supply source 55 located outside the processing container 30 is connected to the upper shower plate 50 via a pipe 56. Plasma generating gas, such as nitrogen, argon, or oxygen, is accumulated in the plasma generating gas supply source 55. The plasma generating gas flows from the plasma generating gas supply source 55 to the upper shower plate 50 via the pipe 56, and is uniformly distributed inside the processing container 30.

A processing gas supply source 60 located outside the processing container 30 is connected to the lower shower plate 51 via a pipe 61. Processing gas, such as tetraethyl orthosilicate (TEOS), is accumulated in the processing gas supply source 60. The processing gas flows from the processing gas supply source 60 to the lower shower plate 51 via the pipe 61, and is uniformly distributed inside the processing container 30.

A lifting unit 65, which suitably lifts the wafer W on the loading table 31 up and down, is placed below the loading table 31. The lifting unit 65 includes three lifting pins 70 and a plate 71, wherein the three lifting pins 70 freely protrude to the top of the loading table 31 and are perpendicularly attached on the plate 71. The plate 71 of the lifting unit 65 is supported by the top of a supporter 72 which penetrates the bottom of the processing container 30. A lifting apparatus 73 located outside the processing container 30 is connected to the bottom of the supporter 72. When the lifting apparatus 73 operates, the three lifting pins 70 penetrating the loading table 31 are lifted up and down, and thus the top of the three lifting pins 70 may protrude upward from the top surface of the loading table 31 or be inserted in the loading table 31.

The three lifting pins 70 of the lifting unit 65 are disposed within a range of an inner side of the carrier arm 11 that is moved to the top of the loading table 31. Accordingly, even when the carrier arm 11 is above the loading table 31, the lifting pins 70 may push up and lift the wafer W above the carrier arm 11. Moreover, when the three lifting pins 70 lift the wafer W, the carrier arm 11 may move in and out above the loading table 31.

An exhaust pipe 76 for evacuating the atmosphere inside the processing container 30 by using an exhaust apparatus 75, such as a vacuum pump, is connected to the bottom of the processing container 30

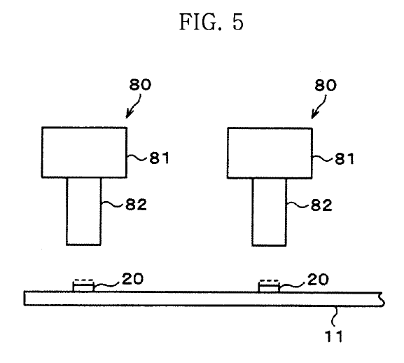

FIG. 5 is a diagram for describing cleaning units 80 according to an embodiment of the present invention. As illustrated in FIG. 5, the plasma processing system 1 includes the cleaning units 80, which clean each of projections 20 on the top of the carrier arms 11 outside the plasma processing apparatuses 5. The cleaning unit 80 includes a source 81 for supplying a cleaning gas, and a cleaning gas nozzle 82 for ejecting the cleaning gas supplied from the source 81 to each of the projections 20. For example, a plasma apparatus which generates active oxygen (radical oxygen) is used as the source 81, and by ejecting the cleaning gas, such as the active oxygen generated by the source 81, to each of the projections 20 via the cleaning gas nozzle 82, the CF based coating material adhered on the surface of the projection 20 is removed, thereby cleaning the projections 20. The cleaning unit 80 may be placed inside the transfer chamber 4.

Operations of the plasma processing system 1 will now be described in detail. Also as an example of plasma treatment, that is, coating the surface (top surface) of wafer W with an insulation layer (SiO₂ layer) by using argon and oxygen as a plasma generating gas and TEOS as a processing gas, will be described.

The wafer W is taken out via the carry-in/out unit 2 from the cassettes 15 and is aligned thereon by the alignment unit 16, and then transferred to any one of the load lock chambers 3. Then, while the load lock chambers 3 and the transfer chamber 4 are maintained in a vacuum state, the wafer W is taken out from the load lock chamber 3 by the carrier arms 11 of the transfer apparatus 10, and then carried into a desired plasma processing apparatus 5.

The wafer W is carried into the processing container 30 of the plasma processing apparatus 5 while being supported by the top surface of the three projections 20 formed on the carrier arm 11, and then is transferred above the loading table 31. Then, by operating the lifting apparatus 73, the three lifting pins 70 of the lifting unit 65 are lifted up, thereby lifting the wafer W supported by the carrier arm 11 above the carrier arm 11. After the wafer W is transferred on the three lifting pins 70 of the lifting unit 65, the carrier arm 11 moves away from the top of the loading table 31, and returns back to the transfer chamber 4. After the carrier arm 11 moves away from the loading table 31, the lifting apparatus 73 is operated so as to lift down the three lifting pins 70, and thereby the wafer W is put on the top surface of the loading table 31.

As such, when the wafer W is put on the loading table 31, the processing container 30 is in an airtight state, and is decompressed as the exhaust pipe 76 evacuates the processing container 30. The plasma generating gas (argon and oxygen) is supplied into the processing container 30 from the upper shower plate 50, and a processing gas (TEOS) for plasma coating is supplied into the processing container 30 from the lower shower plate 51. Then, by operating the microwave supplier 45, an electric field is generated below the transmission window 35, and thus the plasma generating gas is turned into plasma, and the processing gas is additionally turned into plasma, thereby performing a coating process on the wafer W by using an active species generated accordingly.

After performing the coating process for a predetermined time, the operation of the microwave supplier 45 and the supply of the processing gas into the processing container 30 are stopped. Next, the wafer W is carried out from the processing container 30.

The carrying out of the wafer W from the plasma processing apparatus 5 is performed as follows. When the coating process is completed, the three lifting pins 70 are lifted up by the lifting apparatus 73 of the lifting unit 65, thereby lifting the wafer W on the top surface of the loading table 31 above the loading table 31. Then, the carrier arm 11 of the transfer apparatus 10 is moved into the processing container 30, and then above the loading table 31.

After the carrier arm 11 moves in toward a position above the loading table 31, the three lifting pins 70 are lifted down by the lifting apparatus 73. Accordingly, the wafer W is put on the carrier arm 11. Then, the wafer W put on the carrier arm 11 is carried out from the plasma processing apparatus 5 and returned back to the load lock chamber 3. The wafer W that is returned back to the load lock chamber 3 is then returned back to the cassette 15 by the carry-in/out unit 2.

The inner walls of the processing container 30 of the plasma processing apparatus 5 in the plasma processing system 1 may be coated with a coating layer formed of, for example, a CF based coating material. Accordingly, while the coating process is performed on the wafer W in the processing container 30, the inner walls of the processing container 30 are protected from plasma, and thus particles are prevented from being generated from the processing container 30.

Meanwhile, when the inner walls of the processing container 30 of the plasma processing apparatus 5 are coated with the coating layer, the coating layer is also adhered to the top surface of the loading table 31 that is exposed inside the processing container 30, and thus the same coating layer is coated on the top surface of the loading table 31. In this case, the coating layer adhered on the top surface of the loading table 31 is also adhered to the projections 20 formed on the top surface of the carrier arm 11 via the back of the wafer W. Accordingly, when the carrier arm 11 supports the wafer W, the wafer W may easily slide on the projections 20 due to the coating layer, and thus the wafer W may be wrongly transferred or a location of the wafer W may change.

However, according to the plasma processing system 1 of the present invention, the recessed portions 33 are formed on the top surface of the loading table 31, and thus the coating material is not transferred from the top surface of the loading table 31 to the back of the wafer W in regions corresponding to the projections 20 on the top surface of the carrier arm 11. Accordingly, the coating material is not transferred to the projections 20 on the top surface of the carrier arm 11. Consequently, when the wafer W is transferred by the carrier arm 11, the wafer W does not easily slide, and the wafer W can be hardly mistransferred or the location of the wafer W can be hardly misaligned.

Also, according to the plasma processing system 1 of the present invention, each of the projections 20 on the top surface of the carrier arm 11 is cleaned as the cleaning gas is ejected from the cleaning gas nozzle 82 of the cleaning unit 80 towards the projections 20, wherein the cleaning is performed outside the plasma processing apparatus 5. Accordingly, even when the CF based coating material is transferred to the surface of the projections 20, the CF based coating material transferred on the projections 20 can be removed and cleaned outside the plasma processing apparatus 5. According to an embodiment of the present invention, the cleaning of the projections 20 on the top surface of the carrier arm may be performed inside the transfer chamber 4.

According to the plasma processing system 1 of the present invention, the wafer W is not wrongly transferred or the location of the wafer W does not change due to the carrier arm 11. As a result, the efficiency of plasma treatment increases, and productivity increases.

The three projections 20 are formed to support the back of the wafer W, but the number of the projections 20 is not limited thereto. Also, the carrier arm 11 may support the back of the wafer W without using the three projections 20. In order to accurately adjust the temperature of the wafer W on the loading table 31 by using the temperature adjusting unit 32, the areas of the recessed portions 33 when seen from above are minimized so that contacting area of the top surface of the loading table 31 and the back of the wafer W is maximized.

The cleaning units 80, which clean the projections 20 on the carrier arm 11 outside the plasma processing apparatus 5, may not be formed inside the transfer chamber 4 but in other regions. Also, aside from active oxygen, active NF₃ gas (radical NF₃ gas) may be used as the cleaning gas for cleaning the surfaces of the projections 20.

The above embodiments of the present invention have been described in relation to plasma treatment using microwaves, but may also be refer to plasma treatment using high frequency voltage. Moreover, the above embodiments are have been described in relation to plasma treatment for a film forming process, but may also refer to plasma treatment for a substrate process, such as an etching process, besides the film forming process. The substrate processed according to the plasma treatment of the present invention is not limited, and may be a semiconductor wafer, an organic electroluminescence (EL) substrate, or a substrate for flat panel display (FPD).

The present invention may be applied to plasma treatment for processing a substrate by generating plasma inside a processing container.

According to the present invention, since a coating material is not transferred to the top surface of a carrier arm, a substrate does not easily slide on the top surface of the carrier arm. Accordingly, the substrate can be hardly mistransferred or the location of the substrate can be hardly misaligned.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A plasma processing system comprising:
a plasma processing apparatus which processes a substrate in a processing container by turning a processing gas supplied into the processing container into plasma; and
a carrier arm which carries the substrate in and out of the processing container of the plasma processing apparatus,
wherein a loading table is mounted inside the processing container and the substrate is loaded on the top surface of the loading table, and
one or more recessed portions are formed on the top surface of the loading table, in correspondence to one or more locations on the carrier arm for supporting the substrate.

2. The plasma processing system of claim 1, wherein a coating layer is formed on an inner side of the processing container.

3. The plasma processing system of claim 1, wherein the loading table comprises a temperature adjusting unit which adjusts the temperature of the substrate.

4. The plasma processing system of claim 1, wherein a plurality of projections for supporting the back of the substrate are formed on the top surface of the carrier arm, and
the one or more recessed portions are each formed on regions of the top surface of the loading table, wherein the regions correspond to the plurality of projections.

5. The plasma processing system of claim 4, further comprising a cleaning unit, which cleans the plurality of projections formed on the top surface of the carrier arm, outside the processing container.

6. The plasma processing system of claim 5, wherein the cleaning unit comprises a cleaning gas nozzle which ejects cleaning gas to the plurality of projections.
